(19) United States
(12) Patent Application Publication
(10) Pub. No.: US 2026/0130143 A1
(43) Pub. Date: May 7, 2026

(54) METHODS OF DEPOSITING THERMALLY CONDUCTIVE POLYMERIC FILMS

(71) Applicant: Applied Materials, Inc., Santa Clara, CA (US)

(72) Inventors: Xinke Wang, Singapore (SG); Mark Saly, Santa Clara, CA (US); John Sudijono, Singapore (SG); Vicknesh Sahmuganathan, Singapore (SG); Feng Q. Liu, San Jose, CA (US); Bhaskar Jyoti Bhuyan, San Jose, CA (US)

(73) Assignee: Applied Materials, Inc., Santa Clara, CA (US)

(21) Appl. No.: 18/940,363

(22) Filed: Nov. 7, 2024

(51) Int. Cl. H01L 21/02; C09D 161/22; C09D 167/02; C09D 175/02; C09D 175/12; C09D 177/06; C09D 177/12; C23C 10/06; C23C 10/60; C23C 14/14; C23C 14/34; C23C 14/58; C23C 16/02; C23C 16/06; C23C 16/455; C23C 16/56; C23C 28/00; H01L 21/3105; H01L 21/3205

(52) U.S. Cl. CPC H10P 14/683; C09D 161/22; C09D 167/02; C09D 175/02; C09D 175/12; C09D 177/06; C09D 177/12; C23C 10/06; C23C 10/60; C23C 14/14; C23C 14/34; C23C 14/5806; C23C 14/5813; C23C 16/02; C23C 16/06; C23C 16/45525; C23C 16/56; C23C 28/00; H10P 14/412; H10P 14/6334; H10P 14/6512; H10P 14/6514; H10P 95/00

(57) ABSTRACT

Methods of depositing thermally conductive polymeric films are described. Each of the methods include flowing a first precursor over a substrate; removing a first precursor effluent comprising the first precursor; flowing a second precursor over the substrate to react with the first precursor to form the polymeric film on the substrate; and removing a second precursor effluent comprising the second precursor. The methods may include performing a metal deposition process. The methods may include performing a post-treatment process, such as a heat treatment process.

### TECHNICAL FIELD

Embodiments of the disclosure relate to electronic devices and methods of manufacturing electronic devices. More particularly, embodiments of the disclosure are directed to methods of depositing thermally conductive polymeric films.

### BACKGROUND

Generally, an integrated circuit (IC) refers to a set of electronic devices, e.g., transistors, formed on a small chip of semiconductor material, typically silicon. Typically, the IC includes one or more metallization layers having metal lines to connect the electronic devices of the IC to one another and to external connections. Typically, layers of dielectric material are placed between the metallization layers of the IC for insulation.

Semiconductor processing is often guided by ever decreasing node sizes. As dimensions shrink, further challenges arise in many processing steps and structures. This is further complicated for polymeric materials, which are deposited by wet processes, such as spin-coating. Wet processes, however, cannot operate in vacuum environments, and spin-coated polymer materials have a low glass transition temperature (T_{g}) due to low crystallinity.

Accordingly, new methods of depositing thermally conductive polymeric materials are needed.

### SUMMARY

One or more embodiments of the disclosure are directed to methods of depositing polymeric films. In one or more embodiments, a method of depositing a polymeric film comprises: flowing a first precursor over a substrate, the first precursor having a general formula R¹-(X)ₙ, where R¹ comprises one or more of an alkyl group, an alkenyl group, an aryl or aromatic group, and a cycloalkyl group, (X)ₙ comprises one or more of a hydroxide group, an aldehyde group, a ketone group, an acid group, an amino group, an isocyanate group, a thiocyanate group, and an acyl chloride group, and n is an integer in a range of from 1 to 6; removing a first precursor effluent comprising the first precursor; flowing a second precursor over the substrate to react with the first precursor to form the polymeric film on the substrate, the second precursor having a general formula R²-(Y)ₙ, where R² comprises one or more of an alkyl group, an alkenyl group, an aryl or aromatic group, and a cycloalkyl group, (Y)ₙ comprises one or more of a hydroxide group, an aldehyde group, a ketone group, an acid group, an amino group, an isocyanate group, a thiocyanate group, and an acyl chloride group, and n is an integer in a range of from 1 to 6; and removing a second precursor effluent comprising the second precursor.

Additional embodiments of the disclosure are directed to methods of depositing polymeric films. In one or more embodiments, a method of depositing a polymeric film comprises: pre-treating a substrate; flowing a first precursor over the substrate, the first precursor having a general formula R¹-(X)ₙ, where R¹ comprises one or more of an alkyl group, an alkenyl group, an aryl or aromatic group, and a cycloalkyl group, (X)ₙ comprises one or more of a hydroxide group, an aldehyde group, a ketone group, an acid group, an amino group, an isocyanate group, a thiocyanate group, and an acyl chloride group, and n is an integer in a range of from 1 to 6; removing a first precursor effluent comprising the first precursor; flowing a second precursor over the substrate to react with the first precursor to form the polymeric film on the substrate, the second precursor having a general formula R²-(Y)ₙ, where R² comprises one or more of an alkyl group, an alkenyl group, an aryl or aromatic group, and a cycloalkyl group, (Y)ₙ comprises one or more of a hydroxide group, an aldehyde group, a ketone group, an acid group, an amino group, an isocyanate group, a thiocyanate group, and an acyl chloride group, and n is an integer in a range of from 1 to 6; removing a second precursor effluent comprising the second precursor; and performing a heat treatment process.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of the disclosure and are therefore not to be considered limiting of its scope, for the disclosure may admit to other equally effective embodiments. The embodiments described herein are illustrated by way of example and not limitation in the Figures of the accompanying drawings in which like references indicate similar elements.

FIG. 1 illustrates a process flow diagram of a method in accordance with one or more embodiments of the disclosure;

FIG. 2A illustrates a process flow diagram of a method in accordance with one or more embodiments of the disclosure;

FIG. 2B illustrates a process flow diagram of a method in accordance with one or more embodiments of the disclosure;

FIG. 2C illustrates a process flow diagram of a method in accordance with one or more embodiments of the disclosure;

FIG. 2D illustrates a process flow diagram of a method in accordance with one or more embodiments of the disclosure;

FIG. 2E illustrates a process flow diagram of a method in accordance with one or more embodiments of the disclosure;

FIG. 3 illustrates a cross-section view of a substrate in accordance with one or more embodiments of the disclosure; and

FIG. 4 illustrates a cross-section view of a substrate in accordance with one or more embodiments of the disclosure.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

Many of the details, dimensions, angles, and other features shown in the Figures are merely illustrative of particular embodiments. Accordingly, other embodiments can have other details, components, dimensions, angles, and features without departing from the spirit or scope of the present disclosure. In addition, further embodiments of the disclosure can be practiced without several of the details described below.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

Spatially relative terms, such as “beneath,” “below,” “lower,” “above,” “upper” and the like, may be used herein for ease of description to describe one element's relationship to another element(s) or feature(s) as illustrated in the Figures. It will be understood that the spatially relative terms are intended to encompass different orientations of the illustrated structure in use or operation in addition to the orientation depicted in the Figures. For example, if the structure in the Figures is turned over, elements described as “below” or “beneath” other elements would then be oriented “above” the other elements. Thus, the exemplary term “below” may encompass both an orientation of above and below. The structure may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments,” “some embodiments,” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in some embodiments,” “in one embodiment,” or “in an embodiment” in various places throughout this specification are not necessarily referring to the same embodiment of the disclosure. In one or more embodiments, the particular aspects, structures, materials, or characteristics are combined in any suitable manner.

As used in this specification and the appended claims, the term “substrate” or “wafer” can be used interchangeably, both referring to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” or “substrate surface”, as used herein, refers to any portion of a substrate or portion of a material surface formed on a substrate upon which film processing is performed. In some embodiments, the substrate includes a patterned flat substrate.

For example, a substrate surface on which processing can be performed includes materials such as silicon, silicon oxide, silicon nitride, doped silicon, germanium, gallium arsenide, glass, sapphire, and any other materials such as metals, metal nitrides, metal alloys, and other conductive materials, depending on the application.

In some embodiments, the substrate includes at least one conductive material and at least one dielectric material.

Substrates can include, without limitation, semiconductor substrates/semiconductor materials. In some embodiments, the semiconductor substrate comprises one or more of doped or undoped crystalline silicon (Si), doped or undoped crystalline silicon germanium (SiGe), doped or undoped amorphous silicon (Si), or doped or undoped amorphous silicon germanium (SiGe).

Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate. Substrates may have various dimensions, such as 200 mm or 300 mm diameter wafers, as well as rectangular or square panes. In some embodiments, the substrate comprises a rigid discrete material.

The substrate may have one or more features formed therein, one or more layers formed thereon, or combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls comprising, for example, a dielectric material, and a bottom extending into the substrate, the bottom comprising, for example, a metallic material, or vias which have one or more sidewalls extending into the substrate to a bottom.

The features described herein can extend vertically into the substrate and/or laterally within the substrate. Unless specifically indicated otherwise, the features described herein are not limited to either of a vertically extending feature or a laterally extending feature. In one or more embodiments, the substrate comprises at least one vertically extending feature. In one or more embodiments, the substrate comprises at least one laterally extending feature. In one or more embodiments, the substrate comprises at least one vertically extending feature and at least one laterally extending feature.

The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, 40:1, 50:1, 60:1, 70:1, 80:1, 90:1, 100:1, 125:1, or 150:1. In one or more embodiments, the aspect ratio of the features described herein is in a range of from 1:1 to 150:1.

The term “on” indicates that there is direct contact between elements. The term “directly on” indicates that there is direct contact between elements with no intervening elements.

As used in this specification and the appended claims, the terms “reactive compound”, “reactant,” “reactive gas”, “reactive species”, “precursor”, “process gas” and the like are used interchangeably to mean a substance with a species capable of reacting with the substrate or material on the substrate in a surface reaction (e.g., chemisorption, oxidation, reduction, cycloaddition).

A “pulse” or “dose” as used herein refers to a quantity of a source gas that is intermittently or non-continuously introduced into the processing chamber. The quantity of a particular compound within each pulse may vary over time, depending on the duration of the pulse. A particular process gas may include a single compound or a mixture/combination of two or more compounds.

The durations for each pulse/dose are variable and may be adjusted to accommodate, for example, the volume capacity of the processing chamber as well as the capabilities of a vacuum system coupled thereto. Additionally, the dose time of a reactive gas may vary according to the flow rate of the reactive gas, the temperature of the process gas, the type of control valve, the type of processing chamber employed, as well as the ability of the components of the process gas to adsorb onto the substrate. Dose times may also vary based upon the type of layer being formed and the geometry of the device being formed. A dose time should be long enough to provide a volume of compound sufficient to adsorb/chemisorb onto substantially the entire surface of the substrate and form a layer thereon.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

Embodiments of the present disclosure are directed to methods of depositing polymeric films. The disclosure provides various process flows for depositing the polymeric films.

Polymeric materials may be used in semiconductor device manufacturing for a number of structures and processes, including as a thermal interface material (TIM), a mask material, an etch resistant material, a trench fill material, a photoresist material, and a photoresist underlay material, among other applications. More specific examples of applications for polymeric materials include, but are not limited to, the formation of heat dissipation and electrical insulation layers, hot implant hard masks, metal gate (MG)-cut hard masks, metal gate fabrication, reverse tone patterning, self-aligned patterning, and line width roughness (LWR) reduction.

Typically, polymeric materials are deposited by wet processes, such as spin-coating. Wet processes, however, cannot operate in vacuum environments, and spin-coated polymer materials have a low glass transition temperature (T_{g}) due to low crystallinity.

One or more embodiments are directed to thermally conductive polymeric films and dry deposition methods to form thermally conductive polymeric films. Dry deposition methods advantageously provide polymeric films, e.g., thermally conductive polymeric films, having higher crystallinity, higher molecular weight, higher glass transition temperature (T_{g}), and better thickness control (e.g., sub-nanometer thickness control). The dry deposition methods of one or more embodiments facilitate the use of polymeric films, e.g., thermally conductive polymeric films, in a broader range of applications in many different kinds of substrates. For example, in one or more embodiments, the polymeric films, e.g., thermally conductive polymeric films, are configured to be used as thermal interface materials (TIMs).

The thermally conductive polymeric films described herein may be formed by atomic layer deposition (ALD), metal doping, physical vapor deposition (PVD), chemical vapor deposition (CVD), molecular layer deposition (MLD), or vapor phase infiltration (VPI), or combinations thereof. In one or more embodiments, the one or more of atomic layer deposition (ALD), metal doping, physical vapor deposition (PVD), chemical vapor deposition (CVD), molecular layer deposition (MLD), or vapor phase infiltration (VPI) are dry processes that are performed in a vacuum chamber at a pressure less than atmospheric pressure.

In some embodiments, the methods include performing a heat treatment process, such as, but not limited to, one or more of thermal annealing, lithography, focused ion beam, laser annealing, or nanoimprinting.

In specific embodiments, a polymeric film is deposited using molecular layer deposition (MLD), chemical vapor deposition (CVD), or a combination of MLD and CVD. In one or more embodiments, the MLD/CVD methods are used to form polymeric films, followed by a heat treatment process to make large crystalline domains/sizes, which advantageously produce polymeric films with higher thermal conductivity.

In specific embodiments, a polymeric film is deposited using molecular layer deposition (MLD), a metal doping process, physical vapor deposition (PVD), a combination of MLD and the metal doping process, or a combination of MLD and PVD. In one or more embodiments, each of the MLD/metal doping and MLD/PVD methods advantageously introduce various metals to further enhance thermal conductivity of the deposited polymeric films.

In specific embodiments, a polymeric film is deposited using molecular layer deposition (MLD), atomic layer deposition (ALD), or a combination of MLD and ALD. In one or more embodiments, the MLD/ALD methods introduce various metals to further enhance thermal conductivity of the deposited polymeric films. In one or more embodiments, the MLD/ALD methods form organic-inorganic hybrid composite films advantageously having higher thermal conductivity. In one or more embodiments, the MLD/ALD methods form metal oxide films or metal nitride films, each of the metal oxide films or metal nitride films advantageously having higher thermal conductivity.

In specific embodiments, a polymeric film is deposited using molecular layer deposition (MLD), a vapor phase infiltration (VPI) process, or a combination of MLD and VPI. In one or more embodiments, the MLD/VPI methods introduce various metals to further enhance thermal conductivity of the deposited polymeric films. In one or more embodiments, the MLD/VPI methods transform polymeric films deposited by MLD to organic-inorganic hybrid composite films advantageously having higher thermal conductivity.

The VPI process includes, but is not limited to, Multiple Pulsed Infiltration (MPI), Sequential Infiltration Synthesis (SIS), or Sequential Vapor Infiltration (SVI). Each of MPI, SIS, and SVI processes will be understood by a person of ordinary skill in the art without undue experimentation.

In one or more embodiments, the VPI process introduces a metal precursor with or without a co-reactant to incorporate/diffuse metal into the polymeric film. Rather than depositing a film on the surface of a material, VPI “infuses” new constituents into the sub-surface or even the bulk of a material.

Advantageously, the polymeric films deposited in accordance with the methods described herein have enhanced crystallinity (e.g., larger crystal domains/sizes), increased macro-molecular chain alignment, and reinforced inter-chain non-covalent interactions. Advantageously, the polymeric films described herein having enhanced crystallinity (e.g., larger crystal domains/sizes), increased macro-molecular chain alignment, and reinforced inter-chain non-covalent interactions have higher thermal conductivity.

In specific embodiments, the polymeric films have large crystal domains/sizes, such as, for example, greater than or equal to 100 nm. In specific embodiments, the polymeric films have a thermal conductivity in a range of from 1.0 W·m⁻¹·K⁻¹ to 50.0 W·m⁻¹·K⁻¹. In specific embodiments, the polymeric films have a thermal conductivity of about 1.0 W·m⁻¹·K⁻¹. In specific embodiments, the polymeric films have a thermal conductivity of about 5.0 W·m⁻¹·K⁻¹. In specific embodiments, the polymeric films have a thermal conductivity of about 10.0 W·m⁻¹·K⁻¹. In specific embodiments, the polymeric films have a thermal conductivity of about 50.0 W·m⁻¹·K⁻¹.

The thermally conductive polymeric films described herein may be used in, without limitation, electronic devices such as logic devices.

The embodiments of the disclosure are described by way of the Figures, which illustrate process flow diagrams and substrates. The processes shown are merely illustrative possible uses for the disclosed processes, and the skilled artisan will recognize that the disclosed processes are not limited to the illustrated applications.

Embodiments of the present disclosure are directed to methods of depositing polymeric films, e.g., thermally conductive polymeric films are configured to be used as thermal interface materials (TIMs). The disclosure provides various process flows for depositing the polymeric films.

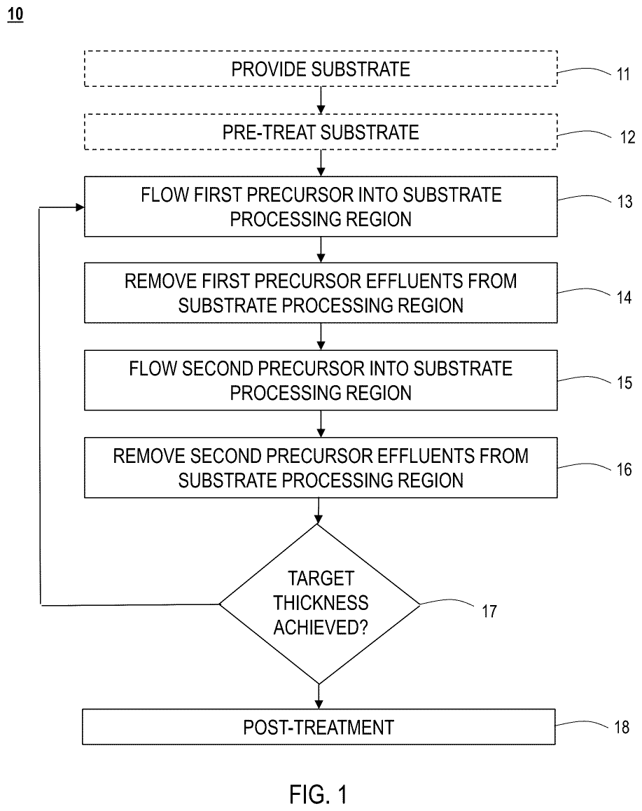

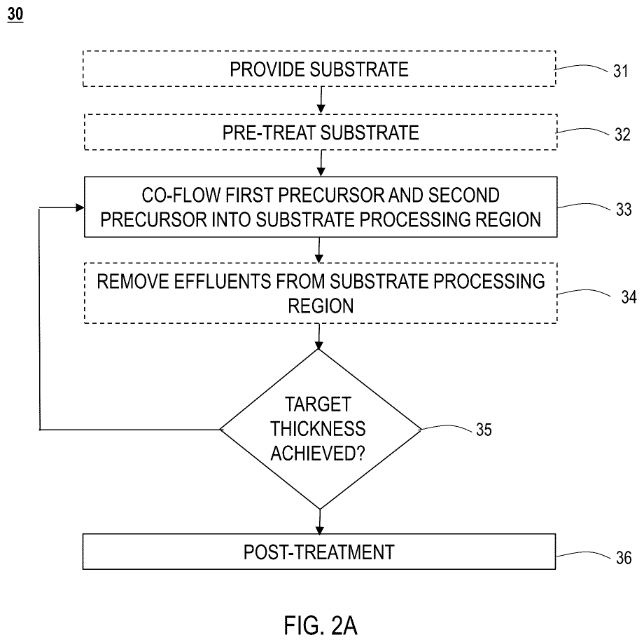

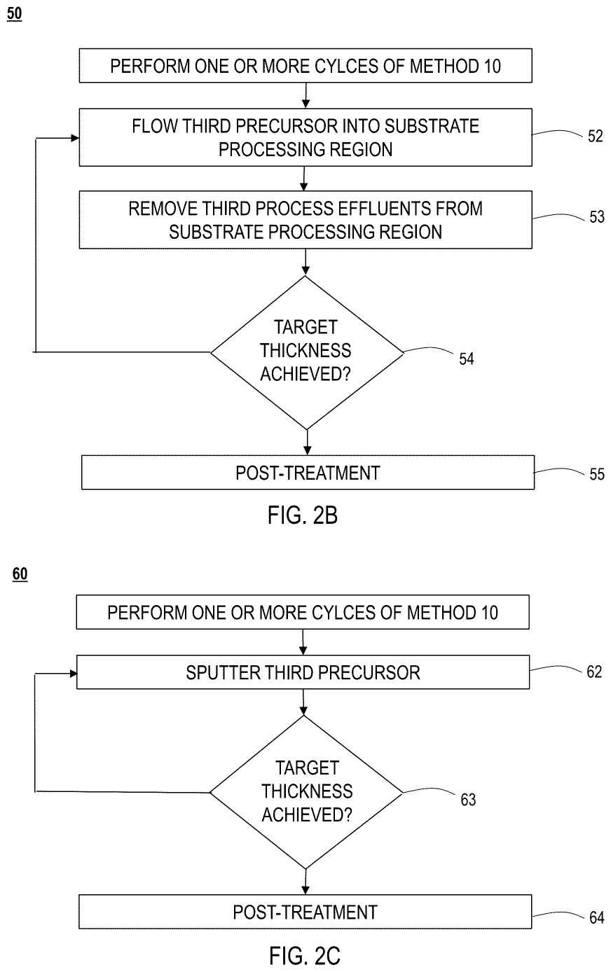

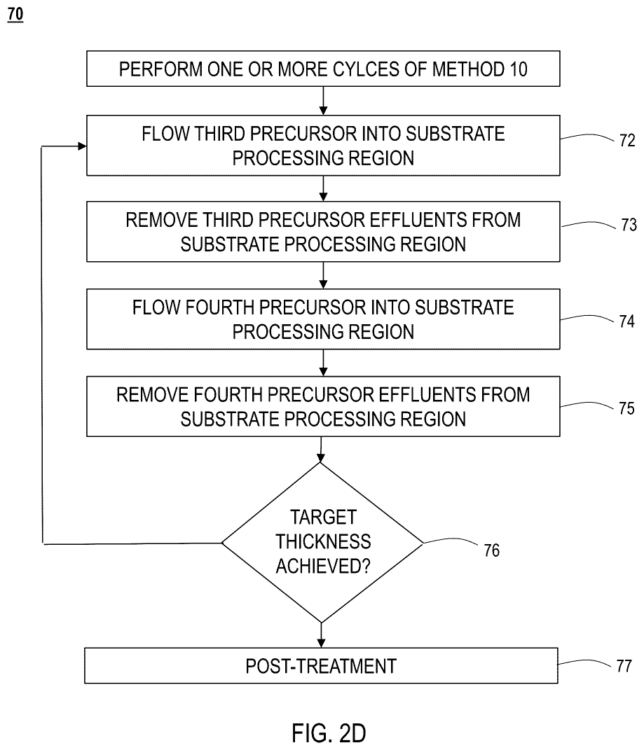

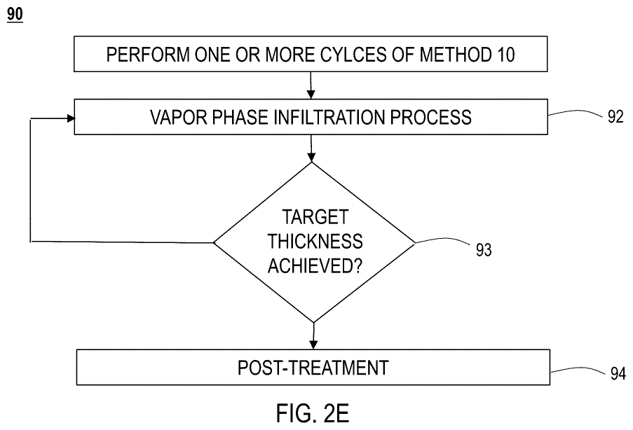

FIG. 1 illustrates a process flow diagram of a method 10 of depositing a polymeric film by molecular layer deposition (MLD) according to one or more embodiments. FIG. 2A illustrates a process flow diagram of a method 30 of depositing a polymeric film by chemical vapor deposition (CVD) according to one or more embodiments. FIG. 2B illustrates a process flow diagram of a method 50 of depositing a polymeric film by a combination of MLD and a metal doping process according to one or more embodiments. FIG. 2C illustrates a process flow diagram of a method 60 of depositing a polymeric film by a combination of MLD and physical vapor deposition (PVD) according to one or more embodiments. FIG. 2D illustrates a process flow diagram of a method 70 of depositing a polymeric film by a combination of MLD and atomic layer deposition (ALD) according to one or more embodiments. FIG. 2E illustrates a process flow diagram of a method 90 of depositing a polymeric film by a combination of MLD and a vapor phase infiltration (VPI) process according to one or more embodiments.

The methods described herein include, but are not limited to, the method 10, the method 30, the method 50, the method 60, the method 70, and the method 90.

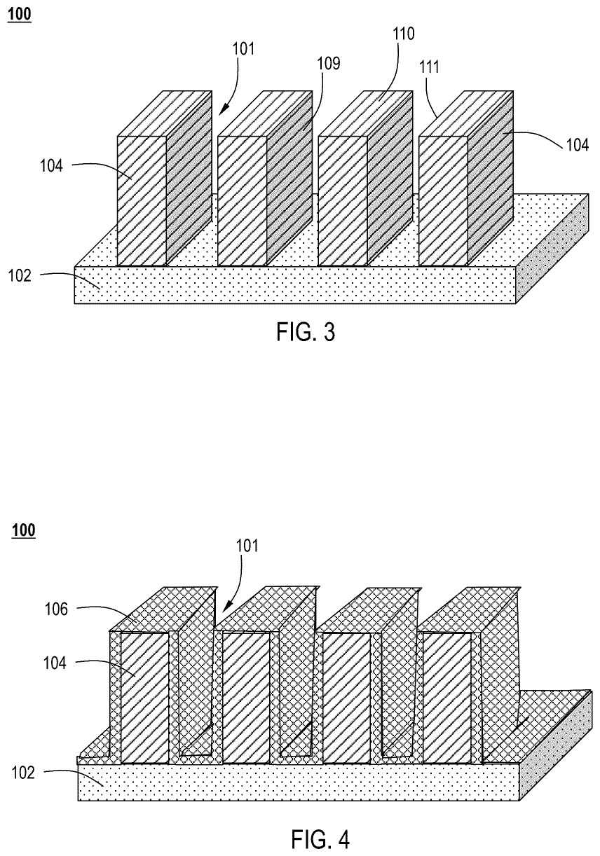

FIGS. 3 and 4 illustrate cross-sectional views of a substrate 102 that may be processed according to the methods described herein.

With reference to FIG. 1, the method 10 comprises, consists essentially of, or consists of: optionally, providing a substrate at operation 11, optionally, pre-treating the substrate at operation 12, flowing a first precursor over the substrate (e.g., into a substrate processing region) at operation 13, removing a first precursor effluent comprising the first precursor from the substrate processing region at operation 14, flowing a second precursor over the substrate (e.g., into the substrate processing region) at operation 15, removing a second precursor effluent comprising the second precursor from the substrate processing region at operation 16, a determination/decision point 17 whether a target thickness of the as-deposited polymeric film has been achieved, and a post-treatment process (e.g., a heat treatment process) at operation 18. In one or more embodiments, the method 10 defines a molecular layer deposition (MLD) process cycle.

With reference to FIG. 2A, the method 30 comprises, consists essentially of, or consists of: optionally, providing a substrate at operation 31, optionally, pre-treating the substrate at operation 32, co-flowing the first precursor and the second precursor over the substrate (e.g., into the substrate processing region) at operation 33, optionally, removing effluents (e.g., the first precursor effluent and/or the second precursor effluent) from the substrate processing region at operation 34, a determination/decision point 35 whether a target thickness of the as-deposited polymeric film has been achieved, and a post-treatment process (e.g., a heat treatment process) at operation 36.

One or more embodiments are directed to a method comprising, consisting essentially of, or consisting of a combination of the method 10 and the method 30.

With reference to FIG. 2B, the method 50 comprises, consists essentially of, or consists of: performing one or more cycles of the method 10 (i.e. performing one or more MLD process cycles), flowing a third precursor over the substrate (e.g., into the substrate processing region) at operation 52, removing a third precursor effluent comprising the third precursor from the substrate processing region at operation 53, a determination/decision point 54 whether a target thickness of the as-deposited polymeric film has been achieved, and a post-treatment process (e.g., a heat treatment process) at operation 55. In one or more embodiments, the method 50 of FIG. 2B includes a combination of MLD and a metal doping process.

With reference to FIG. 2C, the method 60 comprises, consists essentially of, or consists of: performing one or more cycles of the method 10 (i.e. performing one or more MLD process cycles), sputtering the third precursor by physical vapor deposition (PVD) at operation 62, a determination/decision point 63 whether a target thickness of the as-deposited polymeric film has been achieved, and a post-treatment process (e.g., a heat treatment process) at operation 64. In one or more embodiments, the method 60 of FIG. 2C includes a combination of MLD and PVD.

With reference to FIG. 2D, the method 70 comprises, consists essentially of, or consists of: performing one or more cycles of the method 10 (i.e. performing one or more MLD process cycles), flowing a third precursor over the substrate (e.g., into the substrate processing region) at operation 72, removing a third precursor effluent comprising the third precursor from the substrate processing region at operation 73, flowing a fourth precursor over the substrate (e.g., into the substrate processing region) at operation 74, removing a fourth precursor effluent comprising the fourth precursor from the substrate processing region at operation 75, a determination/decision point 76 whether a target thickness of the as-deposited polymeric film has been achieved, and a post-treatment process (e.g., a heat treatment process) at operation 77. In one or more embodiments, the method 70 of FIG. 2D includes a combination of MLD and ALD.

With reference to FIG. 2E, the method 90 comprises, consists essentially of, or consists of: performing one or more cycles of the method 10 (i.e. performing one or more MLD process cycles), performing a vapor phase infiltration (VPI) process at operation 92, a determination/decision point 93 whether a target thickness of the as-deposited polymeric film has been achieved, and a post-treatment process (e.g., a heat treatment process) at operation 94. In one or more embodiments, the method 90 of FIG. 2E includes a combination of MLD and VPI.

As used in this specification and the appended claims, the term “provided” means that the substrate is made available for processing (e.g., positioned in a processing chamber).

Referring to FIGS. 1 and 2A-2E, the methods described herein optionally include pre-treating the substrate. In one or more embodiments, pre-treating the substrate comprises a gas soaking process or a plasma treatment process.

In one or more embodiments, pre-treating the substrate comprises forming a self-assemble monolayer (SAM) on a portion of the substrate to promote deposition of the polymeric film on a particular portion of the substrate. The SAM may comprise any suitable SAM known to the skilled artisan. In one or more embodiments, the SAM comprises 3-aminopropyltrimethoxysilane, ethanolamine, or the like. In one or more embodiments, pre-treating the substrate includes soaking the substrate in a gas such as, but not limited to ammonia (NH₃) and/or hydrazine (N₂H₄). In other embodiments, pre-treating the substrate comprises a plasma treatment. The substrate may be treated with one or more plasma selected from a nitrogen (N₂) plasma, a hydrogen (H₂) plasma, an argon (Ar) plasma, an ammonia (NH₃) plasma, an oxygen (O₂) plasma, and a helium (He) plasma.

Referring still to FIGS. 1 and 2A-2E, the methods described herein include flowing the first precursor into the substrate processing region of a processing chamber and over the substrate. The first precursor binds to the substrate and forms a first portion of the polymeric film.

In one or more embodiments, the first precursor may be a carbon-containing precursor that has at least two reactive groups that can form a bond with a group attached to the substrate. Molecules of the first precursor react with the surface groups of the substrate to form bonds linking the first precursor molecule to the substrate. The reactions between the first precursor molecules and the groups on the substrate continue until most or all the surface groups are bonded to a reactive group on the first precursor molecules. The first portion of the polymeric film blocks further reaction between first precursor molecules in the first precursor effluent and the substrate.

The first precursor may comprise any suitable precursor known to the skilled artisan. In one or more embodiments, the first precursor has a general formula R¹-(X)ₙ, where R¹ comprises one or more of an alkyl group, an alkenyl group, an aryl or aromatic group, and a cycloalkyl group, (X)ₙ comprises one or more of a hydroxide group, an aldehyde group, a ketone group, an acid group, an amino group, an isocyanate group, a thiocyanate group, and an acyl chloride group, and n is an integer in a range of from 1 to 6.

Unless otherwise indicated, the term “lower alkyl,” “alkyl,” or “alk” as used herein alone or as part of another group includes both straight and branched chain hydrocarbons, containing 1 to 20 carbons, or 1 to 10 carbon atoms, in the normal chain, such as methyl, ethyl, propyl, isopropyl, butyl, t-butyl, isobutyl, pentyl, hexyl, isohexyl, heptyl, 4,4-dimethylpentyl, octyl, 2,2,4-trimethyl-pentyl, nonyl, decyl, undecyl, dodecyl, the various branched chain isomers thereof, and the like. Such groups may optionally include up to 1 to 4 substituents. The alkyl may be substituted or unsubstituted.

Such alkyl groups may optionally include up to 1 to 4 substituents such as halo, for example F, Br, Cl, or I, or CF₃, alkyl, alkoxy, aryl, aryloxy, aryl(aryl) or diaryl, arylalkyl, arylalkyloxy, alkenyl, cycloalkyl, cycloalkylalkyl, cycloalkylalkyloxy, amino, hydroxy, hydroxyalkyl, acyl, heteroaryl, heteroaryloxy, heteroarylalkyl, heteroarylalkoxy, aryloxyalkyl, alkylthio, arylalkylthio, aryloxyaryl, alkylamido, alkanoylamino, arylcarbonylamino, nitro, cyano, thiol, haloalkyl, trihaloalkyl, and/or alkylthio, and the like. In one or more embodiments, R¹ is an C₁₋₂₀ alkyl. In other embodiments, R¹ is an C₁₋₁₂ alkyl.

As used herein, the term “alkene” or “alkenyl” or “lower alkenyl” refers to straight or branched chain radicals of 2 to 20 carbons, or 2 to 12 carbons, and 1 to 8 carbons in the normal chain, which include one to six double bonds in the normal chain, such as vinyl, 2-propenyl, 3-butenyl, 2-butenyl, 4-pentenyl, 3-pentenyl, 2-hexenyl, 3-hexenyl, 2-heptenyl, 3-heptenyl, 4-heptenyl, 3-octenyl, 3-nonenyl, 4-decenyl, 3-undecenyl, 4-dodecenyl, 4,8,12-tetradecatrienyl, and the like, and which may be optionally substituted with 1 to 4 substituents, namely, halogen, haloalkyl, alkyl, alkoxy, alkenyl, alkynyl, aryl, arylalkyl, cycloalkyl, amino, hydroxy, heteroaryl, cycloheteroalkyl, alkanoylamino, alkylamido, arylcarbonyl-amino, nitro, cyano, thiol, alkylthio, and/or any of the alkyl substituents set out herein.

As used herein, the term “alkynyl” or “lower alkynyl” refers to straight or branched chain radicals of 2 to 20 carbons, or 2 to 12 carbons, or 2 to 8 carbons in the normal chain, which include one triple bond in the normal chain, such as 2-propynyl, 3-butynyl, 2-butynyl, 4-pentynyl, 3-pentynyl, 2-hexynyl, 3-hexynyl, 2-heptynyl, 3-heptynyl, 4-heptynyl, 3-octynyl, 3-nonynyl, 4-decynyl, 3-undecynyl, 4-dodecynyl, and the like, and which may be optionally substituted with 1 to 4 substituents, namely, halogen, haloalkyl, alkyl, alkoxy, alkenyl, alkynyl, aryl, arylalkyl, cycloalkyl, amino, heteroaryl, cycloheteroalkyl, hydroxy, alkanoylamino, alkylamido, arylcarbonylamino, nitro, cyano, thiol, and/or alkylthio, and/or any of the alkyl substituents set out herein.

The term “halogen” or “halo” as used herein alone or as part of another group refers to chlorine, bromine, fluorine, and iodine as well as CF₃.

As used herein, the term “aryl” refers to monocyclic and bicyclic aromatic groups containing 6 to 10 carbons in the ring portion (such as phenyl, biphenyl or naphthyl, including 1-naphthyl and 2-naphthyl) and may optionally include 1 to 3 additional rings fused to a carbocyclic ring or a heterocyclic ring (such as aryl, cycloalkyl, heteroaryl, or cycloheteroalkyl rings). The aryl group may be optionally substituted through available carbon atoms with 1, 2, or 3 substituents, for example, hydrogen, halo, haloalkyl, alkyl, haloalkyl, alkoxy, haloalkoxy, alkenyl, trifluoromethyl, trifluoromethoxy, alkynyl, and the like.

In specific embodiments, the first precursor comprises one or more of terephthaldehyde, terephthaloyl chloride, 1,3,5-benzenetricarbonyl trichloride, hexamethylene chloride, pyromellitic dianhydride, 1,4-phenylene diisocyanate, or terephthalic acid. In specific embodiments, the first precursor comprises poly(p-phenylene terephthalamide).

In one or more embodiments, the formation rate of the first portion of the polymeric film may depend on the temperature of the substrate as well as the temperature of the deposition precursors that flow into the substrate processing region.

The first precursor effluent may remain in the substrate processing region for a period of time to nearly, or completely, form the first portion of the polymeric film.

Referring still to FIGS. 1 and 2A-2E, first precursor effluents comprising the first precursor are purged or removed from the substrate processing region following formation of the first portion of the polymeric film. The first precursor effluents may be removed by pumping them out of the substrate processing region for a period of time ranging from 0 seconds to about 10,000 seconds. In some embodiments, however, increased purge time may begin to remove reactive sites, which may reduce uniform polymeric film formation. Accordingly, in some embodiments the purge may be performed for less than or equal to 10,000 seconds. In some embodiments, a purge gas may be introduced to the substrate processing region to assist in the removal of the effluents. Exemplary purge gases include, but are not limited to, argon (Ar), helium (He), and nitrogen (N₂).

Referring still to FIGS. 1 and 2A-2E, the methods described herein include flowing the second precursor into the substrate processing region of the processing chamber and over the substrate. The second precursor reacts with the first precursor to form a second portion of the polymeric film.

In one or more embodiments, the second precursor may be a carbon-containing precursor that has at least two reactive groups that can form bonds with unreacted reactive groups of the first precursor that formed the first portion of the polymeric film. Molecules of the second precursor react with the unreacted reactive groups of the first precursor to form bonds linking the second precursor molecules to the first precursor molecules. The reactions between the second and first precursor molecules continue until most or all the unreacted reactive groups on the first precursor molecules have reacted with second precursor molecules. The second portion of the polymeric film blocks further reaction between second precursor molecules in the second precursor effluent and the first portion of the polymeric film.

The second precursor may comprise any suitable precursor known to the skilled artisan. In one or more embodiments, the second precursor has a general formula R²-(Y)ₙ, where R² comprises one or more of an alkyl group, an alkenyl group, an aryl or aromatic group, and a cycloalkyl group, (Y)ₙ comprises one or more of a hydroxide group, an aldehyde group, a ketone group, an acid group, an amino group, an isocyanate group, a thiocyanate group, and an acyl chloride group, and n is an integer in a range of from 1 to 6.

The second precursor may advantageously have functional groups on one end that increase the thickness of the polymeric film. In one or more embodiments, the second precursor includes a reactive group that can form a covalent bond with a reactive group of the first precursor.

In specific embodiments, the second precursor comprises one or more of phenylenediamine, ethylenediamine, hexamethylenediamine, tris(2-aminoethyl)amine, ethanolamine, ethylene glycol, or 4,4′-oxydianiline. In specific embodiments, the second precursor comprises poly(p-phenylene terephthalamide).

In one or more embodiments, the methods also include purging or removing the second precursor effluents from the substrate processing region following the formation of the second portion of the polymeric film. In one or more embodiments, purging or removing the second precursor effluents from the substrate processing region comprises the same process as purging or removing the first precursor effluents from the substrate processing region described herein.

Referring to FIG. 2B-2E, the methods described herein, e.g., the method 50 the method 60, the method 70, and the method 90, independently include performing one or more cycles of the method 10 and performing a metal deposition process.

With reference to FIG. 2B, the metal deposition process comprises a metal doping process (operation 52 and operation 53). The metal doping process of the method 50 comprises doping the polymeric film with a third precursor comprising one or more of aluminum (Al), zinc (Zn), titanium (Ti), tantalum (Ta), tin (Sn), hafnium (Hf), zirconium (Zr), gold (Au), ruthenium (Ru), or tungsten (W).

With reference to FIG. 2C, the metal deposition process comprises a physical vapor deposition (PVD) process (operation 62). The PVD process of the method 60 includes sputtering a third precursor comprising one or more of aluminum (Al), zinc (Zn), titanium (Ti), tantalum (Ta), tin (Sn), hafnium (Hf), zirconium (Zr), gold (Au), ruthenium (Ru), or tungsten (W).

With reference to FIG. 2D, the metal deposition process comprises an atomic layer deposition (ALD) process. The ALD process of the method 70 includes exposing the substrate to a third precursor comprising one or more of aluminum (Al), zinc (Zn), titanium (Ti), tantalum (Ta), tin (Sn), hafnium (Hf), zirconium (Zr), gold (Au), ruthenium (Ru), or tungsten (W) (operation 72), removing a third precursor effluent comprising the third precursor (operation 73), exposing the substrate to a fourth precursor comprising one or more of water (H₂O), ammonia (NH₃), or hydrazine (N₂H₄) (operation 74), and removing a fourth precursor effluent comprising the fourth precursor to form a metallic film on the polymeric film (operation 75).

With reference to FIG. 2E, the metal deposition process comprises a vapor phase infiltration (VPI) process. The VPI process of the method 90 includes diffusing a third precursor comprising one or more of aluminum (Al), zinc (Zn), titanium (Ti), tantalum (Ta), tin (Sn), hafnium (Hf), zirconium (Zr), gold (Au), ruthenium (Ru), or tungsten (W) into the polymeric film to form an organic-inorganic hybrid composite film.

The methods can be performed at any suitable processing conditions, and the processing conditions can vary depending on the type of process flow employed.

In one or more embodiments, the methods described herein may be performed at a temperature in a range of from 20° C. to 300° C. By maintaining an elevated substrate temperature, such as above or about 100° C., for example, in some embodiments, an increased number of nucleation sites may be available along the substrate which may improve formation and reduce void formation by improving coverage at each location.

The polymeric film deposited in accordance with the methods described herein may have any suitable thickness. In one or more embodiments, the polymeric film has a thickness in a range of from 0.1 nm to 200 nm, in a range of from 0.5 nm to 200 nm, in a range of from 1 nm to 20 nm, in a range of from 1 nm to 10 nm, in a range of from 3 nm to 10 nm, or in a range of from 1 nm to 5 nm.

Referring still to FIGS. 1 and 2A-2E, the methods described herein include a determination/decision point whether a target thickness of the as-deposited polymeric film has been achieved. If the target thickness of the as-deposited polymeric film has not been achieved, another respective cycle of the method is performed. If the target thickness of the as-deposited polymeric film has been achieved, another cycle to form another polymeric film is not started. Exemplary numbers of cycles for the formation of polymeric films may include 1 cycle to 2000 cycles, though the disclosure is not limited to any particular number of cycles.

Referring still to FIGS. 1 and 2A-2E, the methods described herein include a post-treatment process. The post-treatment process can be any suitable process.

In one or more embodiments, the post-treatment process comprises a heat treatment process. In one or more embodiments, the heat treatment process includes, but is not limited to, one or more of thermal annealing, lithography, focused ion beam, laser annealing, or nanoimprinting.

In some embodiments, the heat treatment process comprises thermally annealing the polymeric film. In some embodiments, thermal annealing is performed at temperatures greater than about 100° C., or at about 300° C., 400° C., 500° C., 600° C., 700° C., 800° C., 900° C., or 1000° C., or higher. The thermal annealing environment of some embodiments comprises an inert gas (e.g., molecular nitrogen (N₂), argon (Ar)). Annealing can be performed for any suitable length of time. In some embodiments, the polymeric film is thermally annealed for a predetermined time in the range of about 1 second to about 90 minutes, or in the range of about 1 second to about 60 minutes. In or more specific embodiments, thermal annealing comprises a rapid thermal process at 500° C. for 1 min in a nitrogen (N₂) environment. In some embodiments, thermally annealing the polymeric film decreases the roughness of the film and increases the smoothness of the film.

In some embodiments, the polymeric film may be subjected to any suitable lithography process. In some embodiments, the polymeric film may be subjected to any suitable focused ion beam process. In some embodiments, the polymeric film may be subjected to any suitable laser annealing process. In some embodiments, the polymeric film may be subjected to any suitable nanoimprinting process.

Referring to FIGS. 3 and 4, a structure 100 including the substrate 102 and a surface 104 extending from the substrate 102 is illustrated. In one or more embodiments, the surface 104 is a surface of one or more 3D semiconductor structure, such as, but not limited to a photoresist, a mandrel, a trench, a via, a hole, and the like.

In one or more embodiments, as illustrated in FIG. 3, the surface 104 includes a top surface 110, a first sidewall 109, and a second sidewall 111. In one or more embodiments, the surface 104, may have variation along the line edge (surface irregularities), causing line width roughness (LWR) and line edge roughness (LER). In one or more embodiments, as illustrated in FIG. 4, a polymeric film 106 is coated on the surface 104 so as to smooth the surface to reduce LWR and LER. In some embodiments, the polymeric film 106 is deposited on the surface in accordance with the methods described herein, e.g., one or more of the method 10, the method 30, the method 50, the method 60, the method 70, or the method 90.

As recognized by one of skill in the art, there may be more than one surface 104 on the substrate 102. In some embodiments, there are at least two surfaces 104 separated by a feature 101.

In one or more embodiments, the surface 104 on which the polymeric film 106 is formed may include a material in which one or more features 101 may be formed. The features 101 may be characterized by any shape or configuration according to the present technology. In some embodiments, the features 101 may be or include a trench structure, a via structure, or aperture formed within the substrate. Although the features 101 may be characterized by any shapes or sizes, in some embodiments the substrate features 101 may be characterized by higher aspect ratios, or a ratio of a depth of the feature to a width across the feature 101. For example, in some embodiments, substrate features may be characterized by aspect ratios in a range of from 1:1 to 150:1. Additionally, the features 101 may be characterized by narrow widths or diameters across the feature including between two sidewalls, such as a critical dimension in a range of from 5 nm to 500 nm, or in a range of from 10 nm to 200 nm, or in a range of from 20 nm to 100 nm.

In some embodiments, one or more of the surfaces 104 are separated by a distance in a range of from 5 nm to 500 nm, or in a range of from 10 nm to 200 nm, or in a range of from 20 nm to 100 nm. In some embodiments, each of the surfaces 104 are separated by a distance in a range of from 5 nm to 500 nm, or in a range of from 10 nm to 200 nm, or in a range of from 20 nm to 100 nm.

In one or more embodiments, the polymeric film 106 is formed on the substrate 102 and surface 104. In one or more embodiments, deposition of the polymeric film 106 may be substantially conformal. As used herein, a layer which is “substantially conformal” refers to a layer where the thickness is about the same throughout (e.g., on the top, middle and bottom of sidewalls and on the bottom of the feature 101). A layer which is substantially conformal varies in thickness by less than or equal to about 10%, 9%, 8%, 7%, 6%, 5%, 4%, 3%, 2%, 1%, or 0.5%.

Accordingly, in one or more embodiments, the methods described herein further include depositing at least one additional polymeric film on the initial polymeric film, where the initial polymeric film and the at least one additional polymeric film form the polymeric film 106 on the surface 104 of the substrate 102.

In some embodiments where one or more of the surfaces 104 are separated by an initial distance in a range of from 5 nm to 500 nm, or in a range of from 10 nm to 200 nm, or in a range of from 20 nm to 100 nm, or each of the surfaces 104 are separated by an initial distance in a range of from 5 nm to 500 nm, or in a range of from 10 nm to 200 nm, or in a range of from 20 nm to 100 nm, the surfaces 104 are separated by a distance that is less than the initial distance after the polymeric film 106 is deposited.

Once the polymeric film 106 is deposited, the method may optionally include further processing (e.g., bulk deposition of a dielectric film).

The methods described herein can be performed, and the substrate 102 can be processed, in any suitable processing system. The processing system can include any suitable processing chamber(s) used for the fabrication of an electronic device, without limitation, that comprises a polymeric film deposited on a substrate. The particular arrangement of processing chambers and components can be varied depending on the processing system and should not be taken as limiting the scope of the disclosure.

Processes may generally be stored in the memory of a system controller as a software routine that, when executed by the processor, causes the processing system to perform processes of the present disclosure. The software routine may also be stored and/or executed by a second processor (not shown) that is remotely located from the hardware being controlled by the processor. Some or all of the methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the processing system operation such that one or more of the operations of any of the methods described herein are performed.

One or more embodiments of the disclosure are directed to a non-transitory computer readable medium including instructions that, when executed by a controller of a processing system, causes the processing system to perform one or more of the operations of any of the methods described herein.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure includes modifications and variations that are within the scope of the appended claims and their equivalents.

What is claimed is:

1. A method of depositing a polymeric film, the method comprising:
flowing a first precursor over a substrate, the first precursor having a general formula R¹-(X)ₙ, where R¹ comprises one or more of an alkyl group, an alkenyl group, an aryl or aromatic group, and a cycloalkyl group, (X)ₙ comprises one or more of a hydroxide group, an aldehyde group, a ketone group, an acid group, an amino group, an isocyanate group, a thiocyanate group, and an acyl chloride group, and n is an integer in a range of from 1 to 6;
removing a first precursor effluent comprising the first precursor;
flowing a second precursor over the substrate to react with the first precursor to form the polymeric film on the substrate, the second precursor having a general formula R²-(Y)ₙ, where R² comprises one or more of an alkyl group, an alkenyl group, an aryl or aromatic group, and a cycloalkyl group, (Y)ₙ comprises one or more of a hydroxide group, an aldehyde group, a ketone group, an acid group, an amino group, an isocyanate group, a thiocyanate group, and an acyl chloride group, and n is an integer in a range of from 1 to 6; and
removing a second precursor effluent comprising the second precursor.

2. The method of claim 1, further comprising pre-treating the substrate prior to flowing the first precursor, pre-treating the substrate including a gas soaking process or a plasma treatment process.

3. The method of claim 1, wherein the first precursor comprises one or more of terephthaldehyde, terephthaloyl chloride, 1,3,5-benzenetricarbonyl trichloride, hexamethylene chloride, pyromellitic dianhydride, 1,4-phenylene diisocyanate, or terephthalic acid.

4. The method of claim 1, wherein the second precursor comprises one or more of phenylenediamine, ethylenediamine, hexamethylenediamine, tris(2-aminoethyl)amine, ethanolamine, ethylene glycol, or 4,4′-oxydianiline.

5. The method of claim 1, further comprising performing a chemical vapor deposition (CVD) process cycle, the CVD process cycle including exposing the substrate to a co-flow of the first precursor and the second precursor.

6. The method of claim 1, further comprising performing a metal deposition process.

7. The method of claim 6, wherein the metal deposition process comprises a metal doping process, the metal doping process including doping the polymeric film with a third precursor comprising one or more of aluminum (Al), zinc (Zn), titanium (Ti), tantalum (Ta), tin (Sn), hafnium (Hf), zirconium (Zr), gold (Au), ruthenium (Ru), or tungsten (W).

8. The method of claim 6, wherein the metal deposition process comprises a physical vapor deposition (PVD) process, the PVD process including sputtering a third precursor comprising one or more of aluminum (Al), zinc (Zn), titanium (Ti), tantalum (Ta), tin (Sn), hafnium (Hf), zirconium (Zr), gold (Au), ruthenium (Ru), or tungsten (W).

9. The method of claim 6, wherein the metal deposition process comprises an atomic layer deposition (ALD) process, the ALD process including exposing the substrate to a third precursor comprising one or more of aluminum (Al), zinc (Zn), titanium (Ti), tantalum (Ta), tin (Sn), hafnium (Hf), zirconium (Zr), gold (Au), ruthenium (Ru), or tungsten (W), removing a third precursor effluent comprising the third precursor, exposing the substrate to a fourth precursor comprising one or more of water (H₂O), ammonia (NH₃), or hydrazine (N₂H₄), and removing a fourth precursor effluent comprising the fourth precursor to form a metallic film on the polymeric film.

10. The method of claim 6, wherein the metal deposition process comprises a vapor phase infiltration (VPI) process, the VPI process including diffusing a third precursor comprising one or more of aluminum (Al), zinc (Zn), titanium (Ti), tantalum (Ta), tin (Sn), hafnium (Hf), zirconium (Zr), gold (Au), ruthenium (Ru), or tungsten (W) into the polymeric film to form an organic-inorganic hybrid composite film.

11. The method of claim 6, performed at a temperature in a range of from 20° C. to 300° C.

12. The method of claim 1, further comprising performing a heat treatment process, the heat treatment process including one of more of thermal annealing, lithography, focused ion beam, laser annealing, or nanoimprinting.

13. The method of claim 12, wherein the heat treatment process comprises thermally annealing the polymeric film at a temperature greater than or equal to 100°C.

14. A method of depositing a polymeric film, the method comprising:
pre-treating a substrate;
flowing a first precursor over the substrate, the first precursor having a general formula R¹-(X)ₙ, where R¹ comprises one or more of an alkyl group, an alkenyl group, an aryl or aromatic group, and a cycloalkyl group, (X)ₙ comprises one or more of a hydroxide group, an aldehyde group, a ketone group, an acid group, an amino group, an isocyanate group, a thiocyanate group, and an acyl chloride group, and n is an integer in a range of from 1 to 6;
removing a first precursor effluent comprising the first precursor;
flowing a second precursor over the substrate to react with the first precursor to form the polymeric film on the substrate, the second precursor having a general formula R²-(Y)ₙ, where R² comprises one or more of an alkyl group, an alkenyl group, an aryl or aromatic group, and a cycloalkyl group, (Y)ₙ comprises one or more of a hydroxide group, an aldehyde group, a ketone group, an acid group, an amino group, an isocyanate group, a thiocyanate group, and an acyl chloride group, and n is an integer in a range of from 1 to 6;
removing a second precursor effluent comprising the second precursor; and
performing a heat treatment process.

15. The method of claim 14, wherein pre-treating the substrate including a gas soaking process or a plasma treatment process.

16. The method of claim 14, wherein the heat treatment process including one of more of thermal annealing, lithography, focused ion beam, laser annealing, or nanoimprinting.

17. The method of claim 16, wherein the heat treatment process comprises thermally annealing the polymeric film at a temperature greater than or equal to 100°C.

18. The method of claim 14, wherein the first precursor comprises one or more of terephthaldehyde, terephthaloyl chloride, 1,3,5-benzenetricarbonyl trichloride, hexamethylene chloride, pyromellitic dianhydride, 1,4-phenylene diisocyanate, or terephthalic acid, and the second precursor comprises one or more of phenylenediamine, ethylenediamine, hexamethylenediamine, tris(2-aminoethyl)amine, ethanolamine, ethylene glycol, or 4,4′-oxydianiline.

19. The method of claim 14, further comprising performing a chemical vapor deposition (CVD) process cycle, the CVD process cycle including exposing the substrate to a co-flow of the first precursor and the second precursor.

20. The method of claim 14, further comprising performing a metal deposition process prior to performing the heat treatment process, the metal deposition process comprising one or more of:
a metal doping process including doping the polymeric film with a third precursor comprising one or more of aluminum (Al), zinc (Zn), titanium (Ti), tantalum (Ta), tin (Sn), hafnium (Hf), zirconium (Zr), gold (Au), ruthenium (Ru), or tungsten (W);
a physical vapor deposition (PVD) process including sputtering a third precursor comprising one or more of aluminum (Al), zinc (Zn), titanium (Ti), tantalum (Ta), tin (Sn), hafnium (Hf), zirconium (Zr), gold (Au), ruthenium (Ru), or tungsten (W);
an atomic layer deposition (ALD) process including exposing the substrate to a third precursor comprising one or more of aluminum (Al), zinc (Zn), titanium (Ti), tantalum (Ta), tin (Sn), hafnium (Hf), zirconium (Zr), gold (Au), ruthenium (Ru), or tungsten (W), removing a third precursor effluent comprising the third precursor, exposing the substrate to a fourth precursor comprising one or more of water (H₂O), ammonia (NH₃), or hydrazine (N₂H₄), and removing a fourth precursor effluent comprising the fourth precursor to form a metallic film on the polymeric film; or
a vapor phase infiltration (VPI) process including diffusing a third precursor comprising one or more of aluminum (Al), zinc (Zn), titanium (Ti), tantalum (Ta), tin (Sn), hafnium (Hf), zirconium (Zr), gold (Au), ruthenium (Ru), or tungsten (W) into the polymeric film to form an organic-inorganic hybrid composite film.
